(19) United States
(12) Patent Application Publication
(10) Pub. No.: US 2017/0244009 A1
(43) Pub. Date: Aug. 24, 2017

(54) SUBSTRATE FOR COLOR CONVERSION OF LIGHT-EMITTING DIODE AND MANUFACTURING METHOD THEREFOR

(71) Applicant: CORNING PRECISON MATERIALS CO., LTD., Asan-si, Chungcheongnam-do (KR)

(72) Inventors: Ki Yeon LEE, Chungcheongnam-do (KR); Yoon Seuk OH, Chungcheongnam-do (KR); Hyung Soo MOON, Chungcheongnam-do (KR)

(73) Assignee: Corning Precision Materials Co., Ltd., Asan-si, Chungcheongnam-do (KR)

(21) Appl. No.: 15/514,743

(22) PCT Filed: Aug. 7, 2015
(86) PCT No.: PCT/KR2015/008279

§ 371 Date: Mar. 27, 2017

(30) Foreign Application Priority Data
Sep. 26, 2014 (KR) 10-2014-0129236

(51) Int. Cl. H01L 33/50; C09K 11/77; C03C 8/04; C03C 8/14; C03C 4/12; C03C 8/08; H01L 33/56; C09K 11/02

(52) U.S. Cl. CPC H01L 33/505; H01L 33/502; H01L 33/56; C09K 11/7706; C09K 11/025; C03C 8/14; C03C 4/12; C03C 8/08; C03C 8/04; H01L 2933/0083; H01L 2933/0041; H01L 2933/005; C03C 2204/00; C03C 2207/00

(57) ABSTRACT

The present invention relates to a substrate for the color conversion of a light-emitting diode and a manufacturing method therefor and, more specifically, to a substrate for the color conversion of a light-emitting diode and a manufacturing method therefor, which enable a quantum dot (QD) and a structure, in which the QD is supported, to have a color conversion function for implementing white light. To this end, the present invention provides a substrate for the color conversion of a light-emitting diode, comprising: a first glass substrate arranged on a light-emitting diode; a second glass substrate formed to face the first glass substrate; a structure arranged between the first glass substrate and the second glass substrate, having a hollow portion and formed from a mixture of a yellow phosphor and a low-melting point frit glass; a QD filling the hollow portion; and sealing materials respectively formed between the first glass substrate and the lower side of the structure and between the second glass substrate and the upper side of the structure.

### BACKGROUND

Field

The present disclosure generally relates to a color conversion substrate for a light-emitting diode (LED) and a method of fabricating the same. More particularly, the present disclosure relates to a color conversion substrate for an LED, in which not only a quantum dot (QD) but also a structural body containing the QD has a color conversion function for producing white light, and a method of fabricating the same.

Description of Related Art

A light-emitting diode (LED) is a semiconductor device formed of a compound such as gallium arsenide (GaAs) to emit light when an electrical current is applied thereto. The LED uses a p-n junction semiconductor structure into which minority carriers, such as electrons or holes, are injected, such that light is generated by the recombination of electrons and holes.

The characteristics of LEDs include low power consumption, a relatively long lifespan, the ability to be mounted in cramped spaces, and strong resistance to vibrations. LEDs are commonly used in display devices and in the backlight units of display devices. Recently, research into applying LEDs to general illumination devices has been undertaken. In addition to monochromatic LEDs, such as red, blue, or green LEDs, white LEDs have also come onto the market. In particular, a sharp increase in demand for white LEDs is anticipated, in line with the application of white LEDs to vehicle lighting devices and general lighting devices.

In the field of LED technology, white light is commonly generated using two main methods. The first method to generate white light includes disposing monochromatic LEDs, such as red, green, and blue LEDs, adjacently to each other such that various colors of light emitted by the monochromatic LEDs are mixed. However, color tones may change depending on the environment in which such devices are used, since individual monochromatic LEDs have different thermal or temporal characteristics. In particular, color stains may occur, making it difficult to uniformly mix different colors of light. The second method to generate white light includes applying a fluorescent material to an LED and mixing a portion of initial light emitted by the LED and secondary light of which wavelength has been converted by the fluorescent material. For example, a fluorescent material generating yellowish-green or yellow light may be used as a light excitation source on a blue LED, whereby white light can be produced by mixing blue light emitted by the blue LED and yellowish-green or yellow light excited by the fluorescent material. At present, the second method of realizing white light utilizing a blue LED and a fluorescent material is generally used.

Recently, quantum dots (QDs) have been used for color conversion to produce white light. QDs generate relatively strong light within a narrow wavelength, the light being stronger than light generated from a typical fluorescent material. In general, a QD-LED backlight unit generates white light by irradiating yellow QDs with blue light emitted by a blue LED, and applies the white light to a liquid crystal display (LCD) as backlight. LCDs using such a QD-LED backlight unit have high potential as new displays, since the characteristics of such LCDs include superior color reproduction unlike those using a traditional backlight using LEDs only, the ability to realize full color comparable to that of organic light emitting diodes (OLEDs), as well as lower fabrication costs and higher manufacturing productivity than OLED TVs.

In the related art, a method of fabricating such a QD-LED includes: forming a QD sheet by mixing QDs and a polymer; and subsequently coating the QD sheet with a plurality of barrier layers in order to protect the sheet surface from external moisture or the like and to maintain the lifespan of the LED. However, this related-art method is problematic in that fabrication costs are relatively high, due to the barrier layers needing to be applied several times, and most of all, this method fails to entirely protect the QDs from the external environment.

In addition, another method used in the related art includes: etching a glass surface to a certain depth; inserting QDs into the etched portions of the glass surface; covering the resultant structure with a glass cover; applying low melting point glass to the periphery of the glass cover; firing the applied low melting point glass; and sealing the resultant structure using a laser beam. However, the etching process may cause fabrication costs to be increased. In particular, it may be difficult to use a thin glass plate.

In the meantime, since QDs have a short lifespan, when a QD-LED is used for a long period of time, the luminance thereof is reduced due to degradation of QDs. The use of QDs consequently leads to a problem in that it may be difficult to obtain or ensure the lifespan of an LCD using a QD-LED backlight.

### RELATED ART DOCUMENT

Patent Document 1: Korean Patent Application Publication No. 10-2012-0009315 (Feb. 1, 2012)

### BRIEF SUMMARY

Various aspects of the present disclosure provide a color conversion substrate for a light-emitting diode (LED), in which not only a quantum dot (QD) but also a structural body containing the QD has a color conversion function for producing white light, and a method of fabricating the same.

According to an aspect, a color conversion substrate includes: a first glass substrate disposed over an LED; a second glass substrate facing the first glass substrate; a structural body disposed between the first glass substrate and the second glass substrate, having a hollow portion, and formed of a mixture of a yellow fluorescent material and a low melting point glass frit; a QD accommodated in the hollow portion of the structural body; and a sealant disposed between the first glass substrate and a bottom surface of the structural body and between the second glass substrate and a top surface of the structural body.

The yellow fluorescent material may be implemented as a yttrium aluminum garnet (YAG)-based fluorescent material.

The softening point of the low melting point glass frit may be 650° C. or below.

The refractive index of the low melting point glass frit may be 1.7 or greater.

The sealant may be formed of a low melting point glass frit.

A plurality of the structural bodies may be disposed between the first glass substrate and the second glass substrate.

According to another aspect, a method of fabricating a color conversion substrate includes: forming a structural body having a hollow portion and formed of a mixture of a yellow fluorescent material and a low melting point glass frit; disposing the structural body on a first glass substrate; disposing a QD within the hollow portion of the structural body disposed on the first glass substrate; disposing a second glass substrate on the structural body such that the second glass substrate faces the first glass substrate; and sealing a resultant structure by bonding the first glass substrate, the structural body, and the second glass substrate.

The operation of forming the structural body may include: preparing granules by mixing the yellow fluorescent material and powder of the low melting point glass frit; and shaping and sintering the granules into a shape of an rectangular frame.

The operation of disposing the structural body may include fixing the structural body on the first glass substrate by means of a first sealant formed of a low melting point glass frit.

The operation of disposing the second glass substrate may include fixing the second glass substrate on the structural body by means of a second sealant formed of a low melting point glass frit.

The operation of sealing the resultant structure may include bonding the first glass substrate and the structural body to each other and the second glass substrate and the structural body to each other by irradiating the first sealant and the second sealant with laser beams.

According to further another aspect, a method of fabricating a color conversion substrate includes: preparing a paste by mixing a yellow fluorescent material and a low melting point glass frit; forming a structural body having a hollow portion by printing the paste on a first glass substrate; disposing a QD within the hollow portion of the structural body disposed on the first glass substrate; disposing a second glass substrate on the structural body such that the second glass substrate faces the first glass substrate; and sealing a resultant structure by bonding the structural body and the second glass substrate.

The operation of disposing the second glass substrate may include fixing the second glass substrate on the structural body by means of a sealant formed of a low melting point glass frit.

The operation of sealing the resultant structure may include bonding the structural body and the second glass substrate by irradiating the sealant with laser beams.

The yellow fluorescent material may be implemented as a YAG-based fluorescent material.

The low melting point glass frit may have a softening point of 650° C. or below and a refractive index of 1.7 or greater.

According to the present disclosure as set forth above, since the structural body in which the QD is accommodated contains the yellow fluorescent material, not only the QD but also the structural body in which the QD is accommodated can have a color conversion function for producing white light. It is therefore possible to increase or compensate for the lifespan of an LED and the lifespan of a display device using the same in a backlight unit thereof, in which the lifespan would otherwise be reduced due to degradation in the QD.

In addition, according to the present disclosure, since the structural body in which the QD is accommodated is formed of a yellow fluorescent material and a low melting point glass frit, the refractive index of which is similar to the refractive index of the yellow fluorescent material, the luminous efficiency of the LED can be improved.

Furthermore, according to the present disclosure, since the structural body is bonded to the overlying and underlying substrates by means of the sealant formed of a low melting point glass frit, it is possible to provide a hermetic seal to the LED color conversion substrate, the fabrication of which is completed after the bonding by means of the sealant, whereby the QD accommodated within the color conversion substrate can be excellently protected from the external environment.

### BRIEF DESCRIPTION OF THE DRAWINGS

FIG. 1 is a plan view illustrating a color conversion substrate for an LED according to an exemplary embodiment;

FIG. 2 is a cross-sectional view taken along line A-A in FIG. 1;

FIG. 3 is a plan view illustrating a color conversion substrate for an LED according to another exemplary embodiment;

FIG. 4 is a cross-sectional view taken along line B-B in FIG. 3;

FIG. 5 is a process flowchart illustrating a method of fabricating a color conversion substrate for an LED according to an exemplary embodiment;

FIG. 6 to FIG. 9 are process views sequentially illustrating the operations of the method of fabricating a color conversion substrate for an LED according to the exemplary embodiment;

FIG. 10 is a process flowchart illustrating a method of fabricating a color conversion substrate for an LED according to another exemplary embodiment; and

FIG. 11 to FIG. 13 are process views sequentially illustrating the operations of the method of fabricating a color conversion substrate for an LED according to the another exemplary embodiment.

### DETAILED DESCRIPTION

Reference will now be made in detail to a color conversion substrate for a light-emitting diode (LED) and a method of fabricating the same according to the present disclosure, embodiments of which are illustrated in the accompanying drawings and described below, so that a person skilled in the art to which the present disclosure relates could easily put the present disclosure into practice.

Throughout this document, reference should be made to the drawings, in which the same reference numerals and symbols will be used throughout the different drawings to designate the same or like components. In the following description, detailed descriptions of known functions and components incorporated herein will be omitted in the case that the subject matter of the present disclosure is rendered unclear by the inclusion thereof.

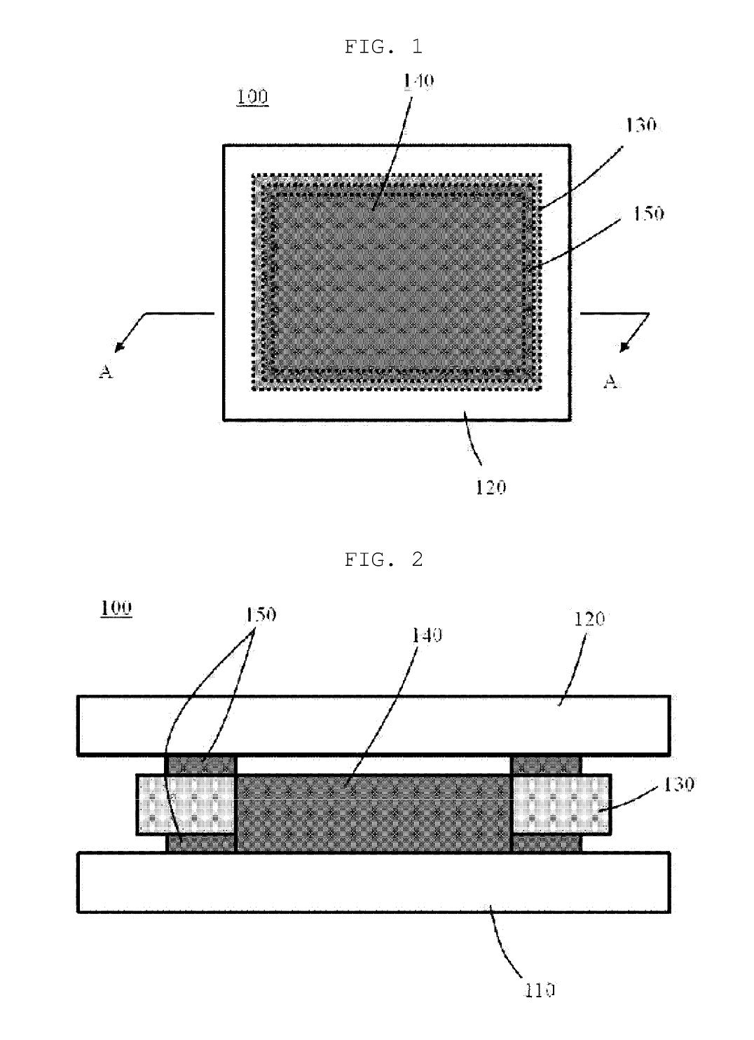

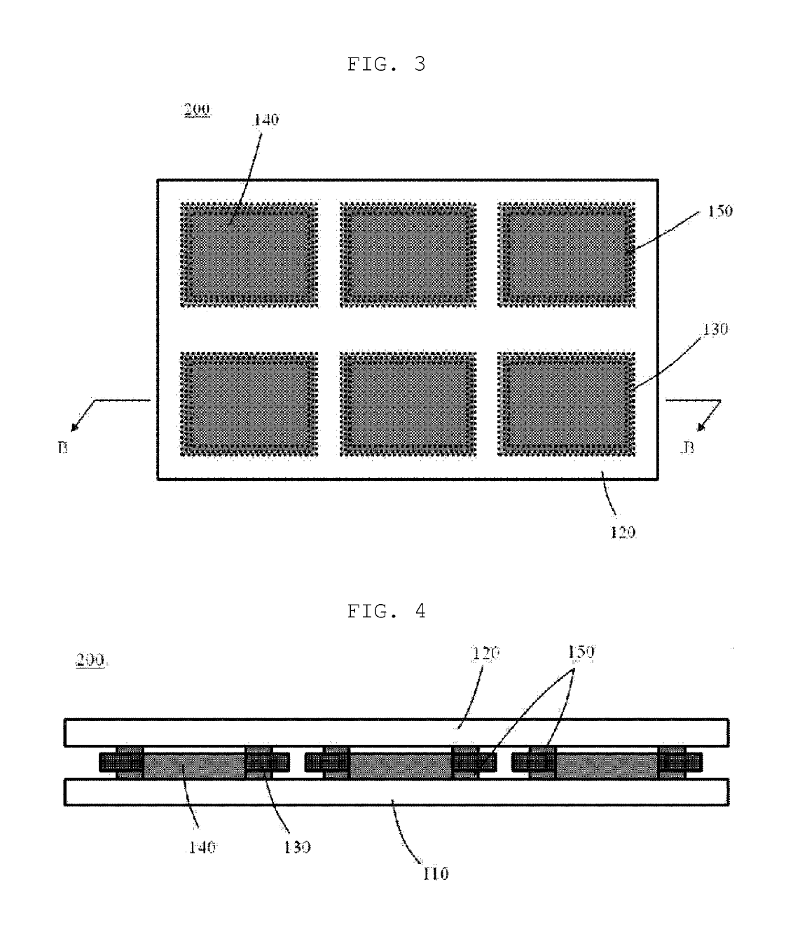

As illustrated in FIG. 1 and FIG. 2, the LED color conversion substrate 100 according to the present embodiment is a substrate disposed over an LED, encapsulating the LED, and converting the color (wavelength) of a portion of light emitted by the LED. Consequently, an LED package including the LED color conversion substrate 100 and, for example, a blue LED radiates white light by mixing blue light emitted by the blue LED and color-converted light excited by the LED color conversion substrate 100. Although not illustrated in the drawings, the LED may include an LED body and an LED chip. The LED body is a structure having a hollow portion in a predetermined shape, providing a structural space for accommodation of the LED chip. The LED body has wires and a lead frame by which the LED chip is electrically connected to an external power source. The LED chip is a light source emitting light when an electrical current is applied thereto from the external power source, is mounted on the LED body, and is connected to the external power source via the wires and the lead frame. The LED chip is implemented as a forward junction of an n-semiconductor layer that provides electrons and a p-semiconductor layer that provides holes.

The LED color conversion substrate 100 according to the present embodiment disposed over an LED as above includes a first glass substrate 110, a second glass substrate 120, a structural body 130, a quantum dot (QD) 140, and a sealant 150.

The first glass substrate 110 is the portion of the LED color conversion substrate 100 disposed adjacently to the LED. The second glass substrate 120 is disposed to face the first glass substrate 110, forming the portion of the LED color conversion substrate 100 positioned farthest from the LED. That is, the first glass substrate 110 and the second glass substrate 120 are spaced apart from each other by means of the structural body 130, the QD 140, and the sealant 150 sandwiched therebetween, such that the first glass substrate 110 and the second glass substrate 120 face each other. The first glass substrate 110 and the second glass substrate 120 act as paths by which light emitted by the LED is externally radiated while protecting the QD 140 accommodated in the structural body 130 from the external environment. For this, transparent glass substrates may be used as the first glass substrate 110 and the second glass substrate 120. According to an exemplary embodiment, the first glass substrate 110 and the second glass substrate 120 may be formed of borosilicate glass or soda lime glass.

The structural body 130 is disposed between the first glass substrate 110 and the second glass substrate 120. The structural body 130 has a hollow portion in the central portion thereof in which the QD 140 is accommodated. As illustrated in FIG. 1 and FIG. 2, the structural body 130 is substantially shaped as an rectangular frame. According to an exemplary embodiment, the structural body 130 may be formed of a mixture of a yellow fluorescent material and a low melting point glass frit. The yellow fluorescent material may be a yttrium aluminum garnet (YAG)-based fluorescent material.

When the structural body 130 contains the yellow fluorescent material, not only the QD 140 but also the structural body 130 in which the QD 140 is accommodated can have a color conversion function for producing white light. When the QD 140 has degraded along with the LED being used for a long period of time, the structural body 130 can consequently compensate for the color conversion function of the QD 140, thereby increasing or compensating for the lifespan of the LED and the lifespan of a display device using the same in a backlight unit thereof.

The low melting point glass frit that forms the structural body 130 together with the yellow fluorescent material may be formed of Bi₂O₃—ZnO—B₂O₃-based glass frit that has a softening point of 650° C. or below and a refractive index of 1.7 or greater. When the low melting point glass frit having a softening point higher than 650° C. is bonded to the first glass substrate 110 and the second glass substrate 120, the first glass substrate 110 and the second glass substrate 120 are susceptible to deformation, since the softening point of the low melting point glass frit is higher than the strain point of either the first glass substrate 110 or the second glass substrate 120. In addition, the refractive index of the low melting point glass frit may be 1.7 or greater, which can similarly match the refractive index of the YAG-based yellow fluorescent material, thereby improving the luminous efficiency of the LED. When the refractive index of the low melting point glass frit does not match the refractive index of the yellow fluorescent material, it may be difficult to obtain a desirable degree of luminous efficiency due to the scattering of light.

In addition, the structural body 130 according to the present embodiment includes a low melting point glass frit, the composition of which is the same as the composition of the low melting point glass frit of the sealant 150, such that the structural body 130 can cooperate with the sealant 150 to form a hermetic seal through laser sealing. This can consequently provide an excellent degree of protection for the QD 140 accommodated within the structural body 130 from the external environment.

The structural body 130 may be fabricated by powder compaction before being bonded to the first glass substrate 110, or may be formed as a paste before being applied on the first glass substrate 110 through printing. These operations will be described in greater detail hereinafter in the method of fabricating a color conversion substrate.

The QD 140 is accommodated within the hollow portion of the structural body 130. The QD 140 is hermetically sealed by the first glass substrate 110, the second glass substrate 120, the structural body 130, and the sealant 150, whereby the QD 140 can be entirely protected from the external environment. The QD 140 is a semiconductor nano-crystal material, the diameter of which ranges from about 1 mn to about 10 nm, and that has a quantum confinement effect. The QD 140 converts the color (wavelength) of light emitted by the LED, thereby generating wavelength-converted light, or fluorescent light. According to the present embodiment, a blue LED may be used as the LED, and the QD 140 is formed of a QD material able to wavelength-convert a portion of light emitted by the blue LED to yellow light in order to produce white light by mixing the yellow light and the blue light.

The sealant 150 is disposed between the first glass substrate 110 and the bottom surface of the structural body 130 and between the second glass substrate 120 and the top surface structural body 130. With this configuration, due to a sealing process of irradiating the sealant 150 with a laser beam, the QD 140 can be hermetically sealed by the first glass substrate 110 and the structural body 130 and by the second glass substrate 120 and the structural body 130, thereby being entirely protected from the external environment. According to the present embodiment, the sealant 150 may be formed of a glass frit, the coefficient of thermal expansion (CTE) of which is equal or similar to the CTE of either the first glass substrate 110, the second glass substrate 120, or the structural body 130, such that the sealant 150 can be bonded thereto by laser sealing. In addition, it is preferable that the sealant 150 be formed of a glass frit, the softening point of which is lower than the softening point of either the first glass substrate 110 or the second glass substrate 120, in order to prevent either the first glass substrate 110 or the second glass substrate 120 from being transformed while firing is being carried out to form the sealant 150 on either the first glass substrate 110 or the second glass substrate 120. For example, the sealant 150 may be formed of a V₂O₅—P₂O₅-based glass frit or a Bi₂O₃—B₂O₃—ZnO-based glass frit that has superior ability to absorb laser light, the wavelength of which ranges from 800 nm to 900 nm. That is, the sealant 150 may be formed of a low melting point glass frit, the composition of which is identical to the composition of the low melting point glass frit of the structural body 130.

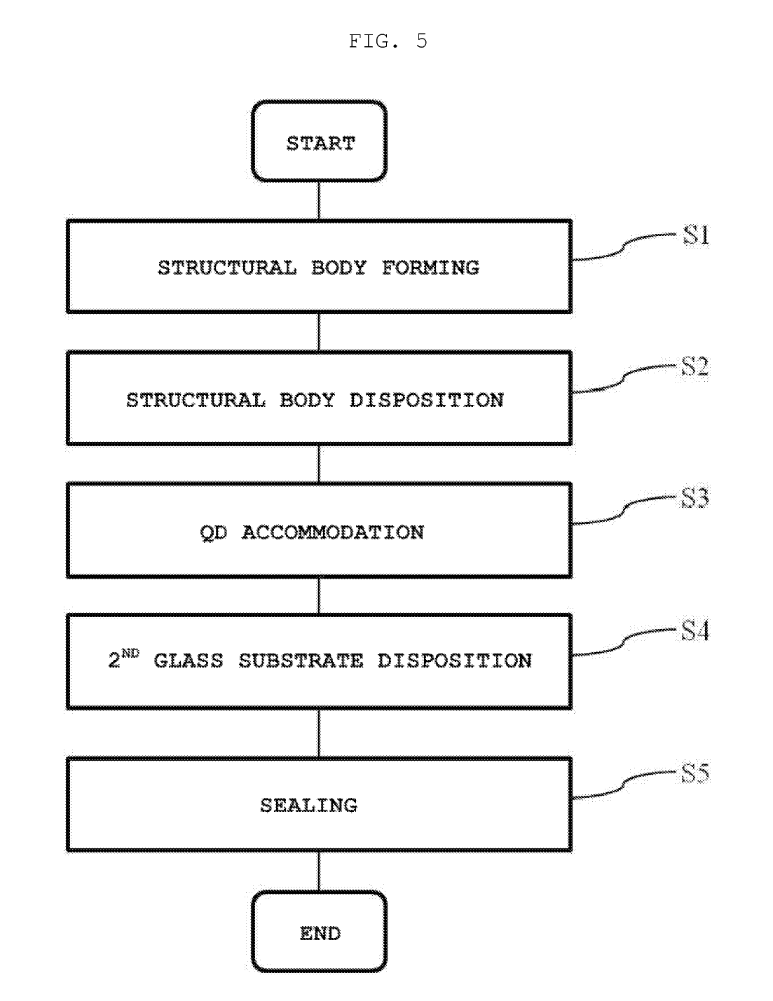

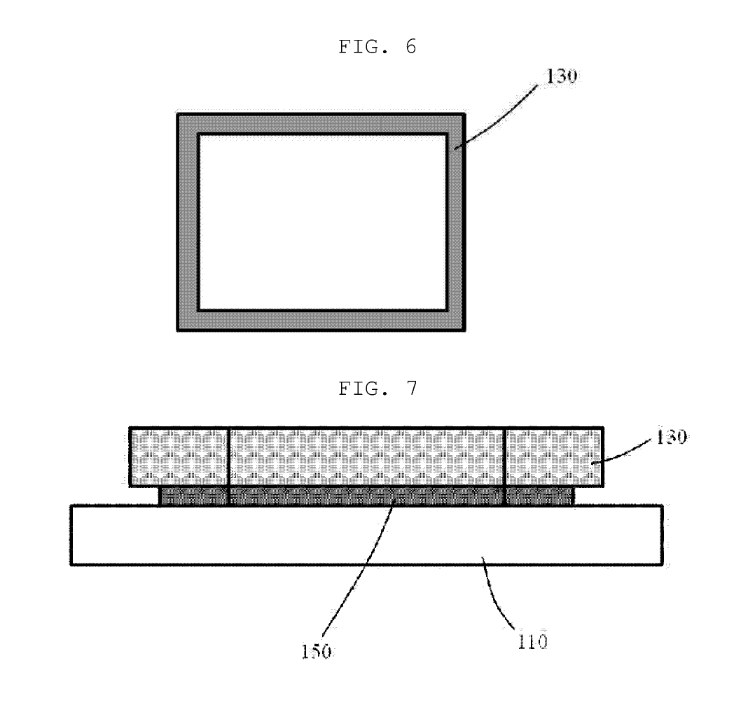

Hereinafter, an LED color conversion substrate according to another exemplary embodiment will be described with reference to FIG. 3 and FIG. 4.

FIG. 3 is a plan view illustrating the LED color conversion substrate according to the another embodiment, and FIG. 4 is a cross-sectional view taken along line B-B in FIG. 3.

As illustrated in FIG. 3 and FIG. 4, the LED color conversion substrate 200 according to the another embodiment is configured such that a plurality of structural bodies 130 are disposed between a first substrate 110 and a second substrate 120 facing the first substrate 110. The present embodiment differs from the former embodiment only in terms of the number of the structural bodies 130 and the resultant number of QDs 140. Therefore, detailed descriptions of the components of the present embodiment will be omitted since they are identical to those of the former embodiment.

The color conversion substrate 200 having this structure may be a substrate applicable to a plurality of LEDs used as a backlight source of a large display or a light source of a wide area lighting device, or may be a bulk substrate intended to be divided into cells, each of which is based on or defined by a single structural body 130, and is applied to a single LED.

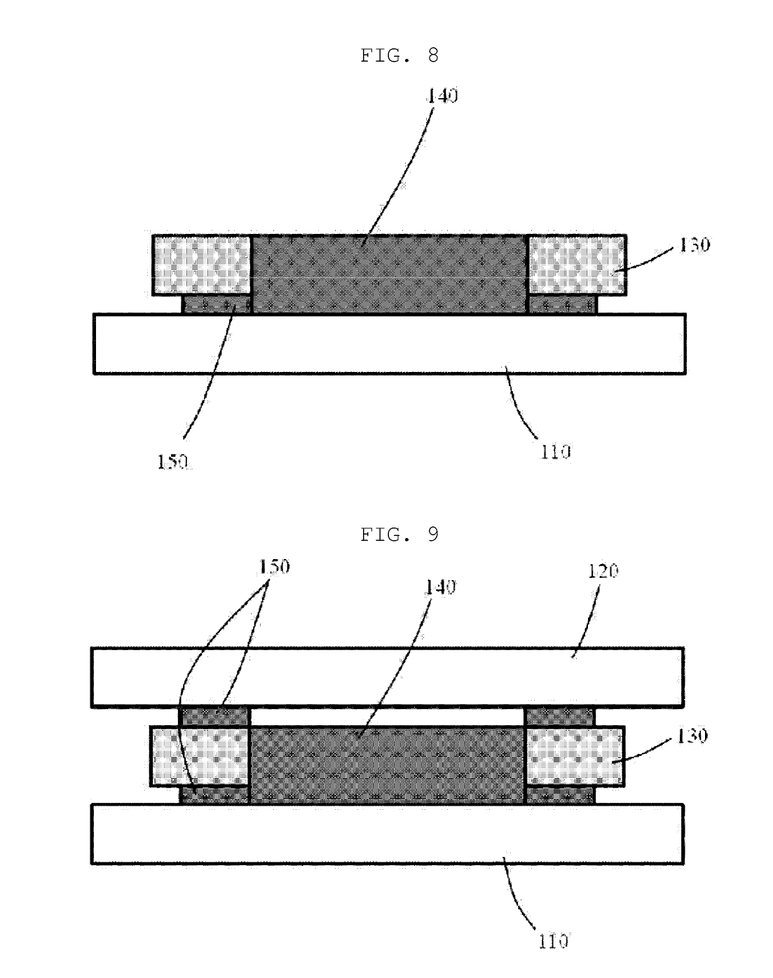

Hereinafter, a method of fabricating an LED color conversion substrate according to an exemplary embodiment will be described with reference to FIG. 5 to FIG. 9.

As illustrated in FIG. 5, the method of fabricating an LED color conversion substrate according to the present embodiment includes structural body forming operation S1, structural body disposing operation S2, QD accommodating operation S3, second glass substrate disposing operation S4, and sealing operation S5.

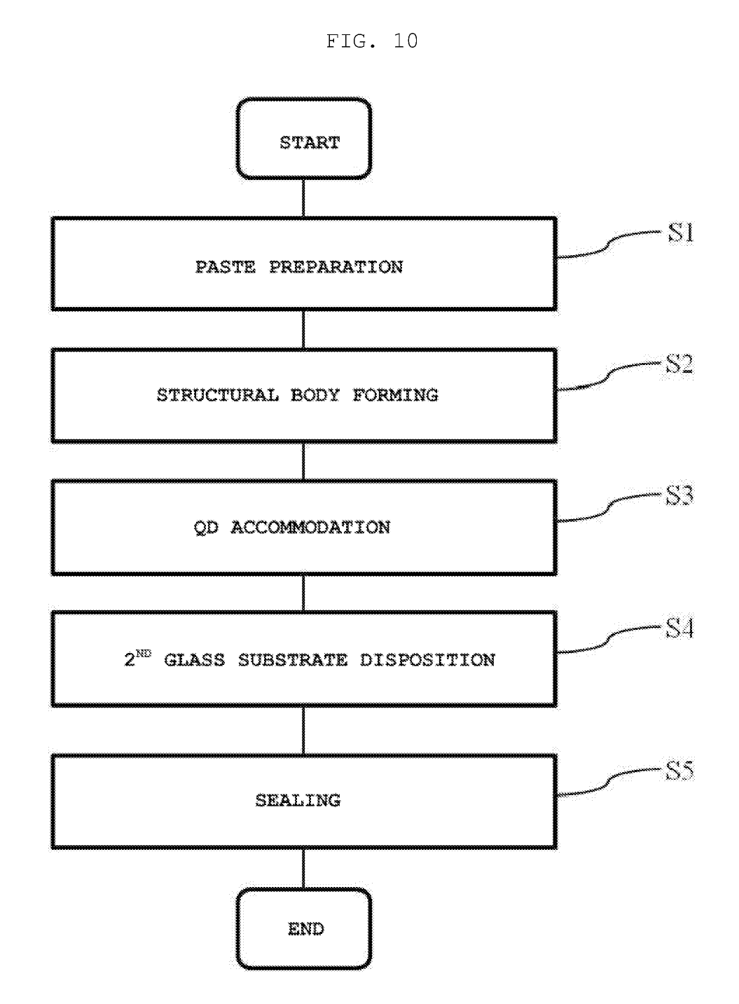

First, as illustrated in FIG. 6, the structural body forming operation S1 is an operation of fabricating a structural body 130 having a hollow portion in the central portion thereof in which a QD (140 in FIG. 8) is to be accommodated. The structural body forming operation S1 includes: forming granules by mixing Bi₂O₃—ZnO—B₂O₃-based low melting point glass frit powder and a YAG-based yellow fluorescent material, the low melting point glass frit powder having a softening point of 650° C. or below and a refractive index of 1.7 or greater; shaping the mixture into the shape of an rectangular frame; and firing the shaped mixture, whereby an rectangular frame-shaped structural body 130 is fabricated.

Afterwards, as illustrated in FIG. 7, the structural body disposing operation S2 is performed to arrange the structural body 130, fabricated in the structural body forming operation S1, on a first glass substrate 110. In the structural body disposing operation S2, the structural body 130 may be fixed on top of the first glass substrate 110 by means of a sealant 150. In the structural body disposing operation S2, the sealant 150 in the form of a paste may be applied to the bottom surface of the structural body 130, i.e. a bonding surface to be bonded to the first glass substrate 110. In addition, in the structural body disposing operation S2, the sealant 150 in the form of a paste may be printed on the first glass substrate 110 in a shape corresponding to the bottom surface of the structural body 130.

The sealant 150 acting as a medium by which the structural body 130 is connected to the first glass substrate 110 as above may be formed of a low melting point glass frit, the softening temperature of which is lower than the softening temperature of the first glass substrate 110. For example, the sealant 150 may be formed of a V₂O₅—P₂O₅-based glass frit or a Bi₂O₃—B₂O₃—ZnO-based glass frit.

Thereafter, as illustrated in FIG. 8, the QD accommodating operation S3 is performed to dispose the QD 140 within the hollow portion of the structural body 130. In the QD accommodating operation S3, a QD material that converts the color (wavelength) of a portion of light emitted by a blue LED into yellow light is accommodated within the hollow portion of the structural body 130.

Afterwards, as illustrated in FIG. 9, the second glass substrate disposing operation S4 is performed to arrange a second glass substrate 120 on the structural body 130 such that the second glass substrate 120 faces the first glass substrate 110. In the second glass substrate disposing operation S4, the second glass substrate 120 is fixed on top of the structural body 130 by means of a sealant 150 formed of a low melting point glass frit, the composition of which is identical to the composition of the sealant disposed between the first glass substrate 110 and the structural body 130. In the second glass substrate disposing operation S4, the sealant 150 in the form of a paste may be applied to the top surface of the structural body 130 or may be printed on the bottom surface of the glass substrate 120 in a shape corresponding to the top surface of the structural body 130, in the same manner as in the structural body disposing operation S2.

Finally, the sealing operation S5 is performed to bond the first glass substrate 110 and the structural body 130 to each other and the structural body 130 and the second glass substrate 120 to each other. In the sealing operation S5, the sealant 150 disposed between the first glass substrate 110 and the structural body 130 and between the structural body 130 and the second glass substrate 120 is irradiated with laser beams, whereby the first glass substrate 110 and the structural body 130 are hermetically bonded by laser sealing and the structural body 130 and the second glass substrate 120 are hermetically bonded by laser sealing.

Upon the completion of the sealing operation S5 as above, an LED color conversion substrate (100 in FIG. 1) is fabricated. When the LED color conversion substrate 100 is fabricated by the fabrication method according to the present embodiment, a related-art multilayer coating process intended to protect the QD can be omitted, thereby reducing fabrication costs compared to those of the related art. In addition, a related-art etching process required for the accommodation of the QD can be omitted, whereby limitations on the thickness of the substrate are removed. In particular, since the structural body 130 is fabricated by powder compaction, the structural body 130 can be mass-produced at a lower cost.

In the method of fabricating an LED color conversion substrate according to the present embodiment, the method of fabricating a single cell has been described. However, it is possible to fabricate a bulk color conversion substrate (200 in FIG. 3) for an array of a plurality of LEDs applicable as a backlight source of a display or a light source of a wide area lighting device by fabricating a plurality of structural bodies 130, arranging the plurality of structural bodies 130 on a single first glass substrate 110, and performing a series of the QD accommodating operation S3, the second glass substrate disposing operation S4, and the sealing operation S5 as above. In addition, after the bulk color conversion substrate (200 in FIG. 3) is fabricated through this process, the bulk color conversion substrate (200 in FIG. 3) may be diced into cells defined by the plurality of structural bodies 130 respectively, thereby facilitating the mass production of color conversion substrates (100 in FIG. 1) applied to individual LEDs.

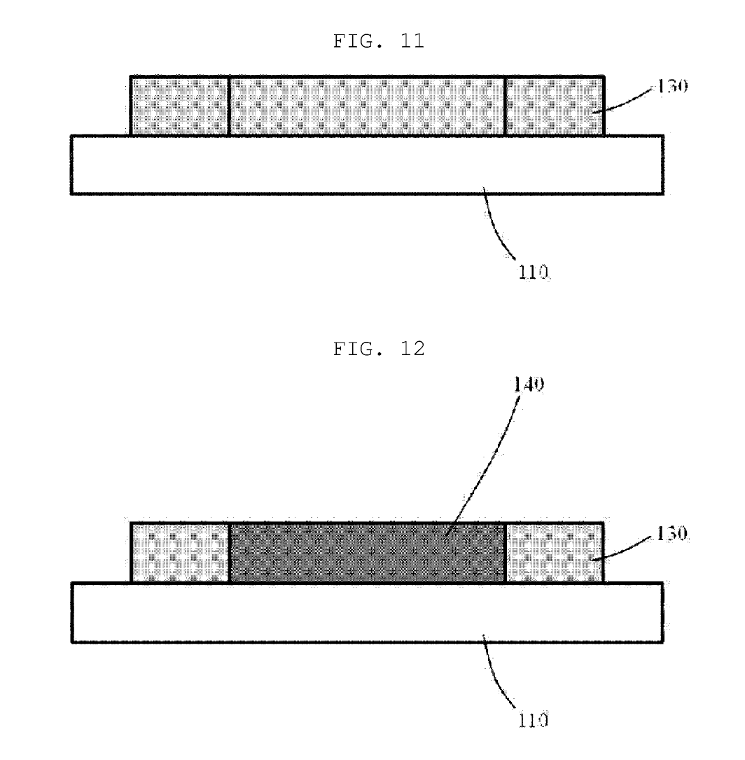

Hereinafter, a method of fabricating an LED color conversion substrate according to another exemplary embodiment will be described with reference to FIG. 10 to FIG. 13.

As illustrated in FIG. 10, the method of fabricating an LED color conversion substrate according to the present embodiment includes paste preparing operation S1, structural body forming operation S2, QD accommodating operation S3, second glass substrate disposing operation S4, and sealing operation S5.

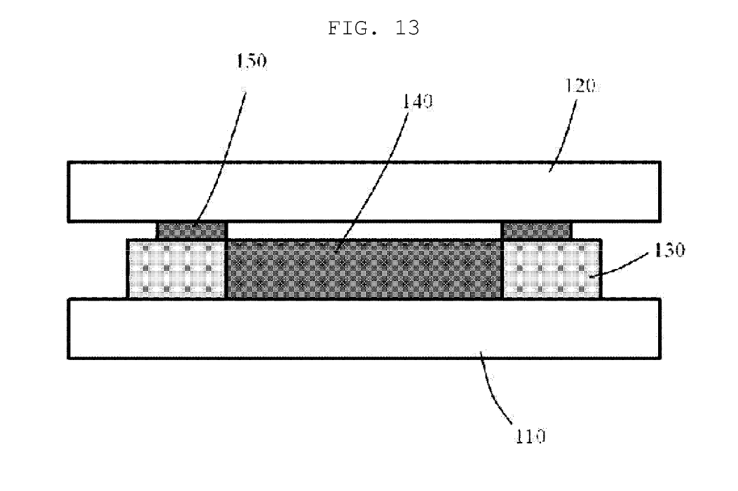

First, in the paste preparing operation S1, a paste is prepared by adding and mixing a YAG-based yellow fluorescent material and low melting point glass frit powder. Afterwards, as illustrated in FIG. 11, in the structural body forming operation S2, a structural body 130 having a hollow portion is formed by printing the paste prepared in the paste preparing operation S1 on a first glass substrate 110. Thereafter, as illustrated in FIG. 12 and FIG. 13, a series of operations including the QD accommodating operation S3, the second glass substrate disposing operation S4, and the sealing operation S5 may be sequentially performed. Detailed descriptions of the QD accommodating operation S3, the second glass substrate disposing operation S4, and the sealing operation S5 identical to those described in the former embodiment will be omitted.

The method of fabricating an LED color conversion substrate according to the present embodiment forms the structural body 130 on the first glass substrate 110 by printing, unlike the method of fabricating an LED color conversion substrate according to the former embodiment in which the structural body 130 is formed by powder compaction. According to the present embodiment, the sealant 150 disposed between the first glass substrate 110 and the structural body 130 in the method of fabricating an LED color conversion substrate according to the former embodiment can be omitted. Accordingly, in the method of fabricating an LED color conversion substrate according to the present embodiment, the sealant 150 may be disposed only between the structural body 130 and the second glass substrate 120, and is subsequently bonded thereto by laser sealing.

The foregoing descriptions of specific exemplary embodiments of the present disclosure have been presented with respect to the drawings. They are not intended to be exhaustive or to limit the present disclosure to the precise forms disclosed, and obviously many modifications and variations are possible for a person having ordinary skill in the art in light of the above teachings.

It is intended therefore that the scope of the present disclosure not be limited to the foregoing embodiments, but be defined by the Claims appended hereto and their equivalents.

### DESCRIPTION OF REFERENCE NUMERALS

100, 200: color conversion substrate
110: first glass substrate
120: second glass substrate
130: structural body
140: quantum dot

1. A color conversion substrate comprising:
a first glass substrate disposed over a light-emitting diode;
a second glass substrate facing the first glass substrate;
at least one structural body disposed between the first glass substrate and the second glass substrate, having a hollow portion, and formed of a mixture of a yellow fluorescent material and a low melting point glass frit;
a quantum dot accommodated in the hollow portion of the at least one structural body; and
a sealant disposed between the first glass substrate and a bottom surface of the at least one structural body and between the second glass substrate and a top surface of the at least one structural body.

2. The color conversion substrate of claim 1, wherein the yellow fluorescent material comprises a yttrium aluminum garnet-based fluorescent material.

3. The color conversion substrate of claim 1, wherein a softening point of the low melting point glass frit is 650° C. or below.

4. The color conversion substrate of claim 1, wherein a refractive index of the low melting point glass frit is 1.7 or greater.

5. The color conversion substrate of claim 1, wherein the sealant is formed of a low melting point glass frit.

6. The color conversion substrate of claim 1, wherein the at least one structural body comprises a plurality of structural bodies disposed between the first glass substrate and the second glass substrate.

7. A method of fabricating a color conversion substrate comprising:
forming at least one structural body having a hollow portion and formed of a mixture of a yellow fluorescent material and a low melting point glass frit;
disposing the at least one structural body on a first glass substrate;
disposing a quantum dot within the hollow portion of the at least one structural body disposed on the first glass substrate;
disposing a second glass substrate on the at least one structural body such that the second glass substrate faces the first glass substrate; and
sealing a resultant structure by bonding the first glass substrate, the at least one structural body, and the second glass substrate.

8. The method of claim 7, wherein forming the at least one structural body comprises:
preparing granules by mixing the yellow fluorescent material and powder of the low melting point glass frit; and
shaping and sintering the granules into a shape of an rectangular frame.

9. The method of claim 7, wherein disposing the at least one structural body comprises fixing the at least one structural body on the first glass substrate by means of a first sealant formed of a low melting point glass frit.

10. The method of claim 9, wherein disposing the second glass substrate comprises fixing the second glass substrate on the at least one structural body by means of a second sealant formed of a low melting point glass frit.

11. The method of claim 10, wherein sealing the resultant structure comprises bonding the first glass substrate and the at least one structural body to each other and the second glass substrate and the at least one structural body to each other by irradiating the first sealant and the second sealant with laser beams.

12. A method of fabricating a color conversion substrate comprising:
preparing a paste by mixing a yellow fluorescent material and a low melting point glass frit;
forming at least one structural body having a hollow portion by printing the paste on a first glass substrate;
disposing a quantum dot within the hollow portion of the at least one structural body disposed on the first glass substrate;
disposing a second glass substrate on the at least one structural body such that the second glass substrate faces the first glass substrate; and
sealing a resultant structure by bonding the at least one structural body and the second glass substrate.

13. The method of claim 12, wherein disposing the second glass substrate comprises fixing the second glass substrate on the at least one structural body by means of a sealant formed of a low melting point glass frit.

14. The method of claim 13, wherein sealing the resultant structure comprises bonding the at least one structural body and the second glass substrate by irradiating the sealant with laser beams.

15. The method of claim 12, wherein the yellow fluorescent material comprises a yttrium aluminum garnet-based fluorescent material.

16. The method of claim 12, wherein the low melting point glass frit has a softening point of 650° C. or below and a refractive index of 1.7 or greater.

17. The method of claim 7, wherein the yellow fluorescent material comprises a yttrium aluminum garnet-based fluorescent material.

18. The method of claim 7, wherein the low melting point glass frit has a softening point of 650° C. or below and a refractive index of 1.7 or greater.
